(19) United States
(12) Patent Application Publication
(10) Pub. No.: US 2012/0072140 A1
(43) Pub. Date: Mar. 22, 2012

(54) Systems, methods, and devices for analyzing utility usage with load duration curves

(75) Inventors: Peter Cowan, Victoria (CA); John C. Van Gorp, Sidney (CA); Daniel J. Wall, Saanichton (CA)

(73) Assignee: Schneider Electric USA, Inc., Palatine, IL (US)

(21) Appl. No.: 12/886,715

(22) Filed: Sep. 21, 2010

(51) Int. Cl. G01R 21/06; G06F 19/00

(52) U.S. Cl. 702/60

(57) ABSTRACT

Systems, methods, and devices for regulating usage of at least one utility by a utility consuming system. One aspect of the present disclosure is directed to a method for regulating usage of at least one utility by a utility consuming system having a plurality of utility consuming segments. The method includes: generating a load duration curve (LDC); selecting a portion of the LDC to be analyzed; generating an associated duration chart (ADC) that is indicative of one or more associated duration parameters relating to the selected portion of the LDC; and modifying usage of the utility by at least one of the utility consuming segments based, at least in part, upon the one or more associated duration parameters indicated in the first ADC.

### FIELD OF THE INVENTION

The present invention relates generally to utility monitoring systems and, more particularly, to systems, methods, and devices for analyzing utility usage with load duration curves.

### BACKGROUND

Utility companies typically charge facilities for their consumption of electrical power supplied by the utility company based upon the facility's peak demand consumption. These rates are set for a duration, such as one year, even though the facility may actually consume its peak consumption for a small fraction of the entire year. For example, if a facility's peak consumption is 1000 kilowatts (kW) for one 15 minute period during the entire year, the utility company may charge the facility based upon a peak consumption of 1000 kW. If the time and date of a facility's peak consumption can be pinpointed, ameliorative steps can be taken to reduce peak demand during those times. During the next renewal period, if the facility can reduce its overall peak consumption, it can realize significant cost savings over the entire contractual period. Other utility companies that supply water, air, gas, or steam may charge for the consumption of these utilities based upon a similar peak usage model.

The concepts of “load curves” and “load duration curves” are known to utilities, for example, for transmission and distribution capacity planning. Load duration curves (LDCs) are used to illustrate the relationship between generating capacity requirements and capacity utilization. Unlike typical load curves, the demand data in an LDC is ordered in descending order of magnitude, rather than chronologically. The LDC curve shows the capacity utilization requirements for each increment of load. For example, LDCs are often used to show the capacity of a transmission line by highlighting the percent of time the line is subjected to varying load levels, where the load may be represented by a measurement, such as kW demand.

LDCs are often generated over a period of weeks or months, and used as a static view to find what percentage of time the electrical system is at a certain capacity. In addition, LDCs are generally not configured to provide details about the high-load portion of the curve, or to allow direct comparisons of actual capacity planning metrics or measurements against each other. Moreover, LDCs typically do not allow the user to view the impact of loads chronologically or geographically. Consequently, the user does not know where or when a peak load may occur. When the LDC is generated over a large span of time, the impact of a peak may therefore be difficult to observe. For this reason, LDCs are typically used by utilities, and show the number of hours or days that a demand exceeds a certain load demand level and indicate where there is a need for load control. As this information is often very general, current LDCs are difficult to use in building and industrial applications, where much more granular detail is required to help with capacity planning, reduction of peak demand consumption, and other facility management.

### SUMMARY

A need has been identified for systems, methods and devices that are capable of producing highly accurate and detailed information for use in achieving more efficient facilities operation, utility consumption, and cost containment. In an aspect of the present disclosure, this and other needs are satisfied by adding one or more additional “dimensions” to an LDC, where one or more forms of associated duration information are generated and presented along with the Load Duration Curves. Capacity planning typically includes the use of categories and metrics to help the user understand the drivers behind periods of high load; thus, the user is more fully informed and able to take more meaningful responsive action on the system. By splitting and filtering the “data” of the typical LDC and aligning the data with associated duration information, the actionable items the users can take on the high-load portion of the LDC can have a dramatic impact on reducing desired capacity characteristics.

According to one embodiment of the present disclosure, a method of analyzing usage of at least one utility by a utility consuming system is presented. The method comprises: generating a first load duration curve (LDC); receiving a selection of a portion of the first LDC to be analyzed; generating a first associated duration chart (ADC) indicative of one or more associated duration parameters relating to the selected portion of the first LDC; and storing the generated first ADC in association with the generated first LDC.

According to another embodiment of the present disclosure, one or more non-transitory, machine-readable storage media are featured. The one or more non-transitory, machine-readable storage media include instructions which, when executed by one or more processors, cause the one or more processors to perform operations associated with a utility monitoring system. These operations comprise: accumulating demand interval data collected by at least one utility monitoring device in the utility monitoring system, the demand interval data including a number of utility usage rate values and associated temporal data; generating a load duration curve (LDC) from at least some of the accumulated demand interval data; generating an associated duration chart (ADC) indicative of one or more associated duration parameters relating to a selected portion of the LDC; and storing the generated first ADC in association with the generated first LDC.

In accordance with yet another embodiment, a system is presented for monitoring usage of at least one utility by a utility consuming system. The monitoring system includes at least one utility monitoring device that is configured to accumulate demand interval data from the utility consuming system. The demand interval data includes a number of utility usage rate values and associated temporal data. The system also includes a display device, a user interface, and at least one controller. The controller is configured to: receive, via the user interface, a selection of a type of load duration curve (LDC) to be generated; receive, via the user interface, a selection of a type of associated duration chart (ADC) to be generated; generate an LDC based on at least some of the accumulated demand interval data and the selected type of LDC; generate an ADC indicative of one or more associated duration parameters relating to the generated LDC, the ADC being generated based on the selected type of ADC; and command the display device to display the generated LDC and the generated ADC.

The above summary is not intended to represent each embodiment or every aspect of the present disclosure. Rather, the foregoing summary merely provides an exemplification of some of the novel features included herein. The above features and advantages, and other features and advantages of the present disclosure, will be readily apparent from the following detailed description of the embodiments and best modes for carrying out the present invention when taken in connection with the accompanying drawings and appended claims.

### BRIEF DESCRIPTION OF THE DRAWINGS

FIG. 1 is a schematic illustration of an exemplary utility monitoring system according to aspects of the various embodiments disclosed herein.

FIG. 2 is a flowchart of an exemplary algorithm according to aspects of the various embodiments disclosed herein.

FIG. 3A illustrates an exemplary Load Duration Curve (LDC) according to aspects of the various embodiments disclosed herein.

FIG. 3B illustrates an exemplary Associated Duration Chart (ADC) according to aspects of the various embodiments disclosed herein.

FIG. 4A illustrates an exemplary LDC according to aspects of the various embodiments disclosed herein, showing selection of a particular portion of the LDC for analysis.

FIG. 4B illustrates an exemplary ADC that is generated in response to the selection illustrated in FIG. 4A.

FIG. 5A illustrates an exemplary LDC according to aspects of the various embodiments disclosed herein, showing a representative actual load duration curve and a representative optimized load duration curve.

FIG. 5B illustrates an exemplary ADC that was generated for the LDC of FIG. 5A, showing aggregated kilowatt of demand (kWd) broken down by load type, and further showing a selected modification to one of the loads.

FIG. 5C illustrates an exemplary ADC that was generated for the LDC of FIG. 5A, showing aggregated kilowatt of demand (kWd) broken down by load type and day.

FIG. 6A illustrates an exemplary Load Duration Curve (LDC) graphed together with a corresponding exemplary Associated Duration Chart (ADC) in a 3-dimensional format according to aspects of the various embodiments disclosed herein.

FIG. 6B is a 2-dimensional plan-view illustration of a 3-dimensional plot of an exemplary LDC shown in combination with an exemplary ADC according to aspects of the various embodiments disclosed herein.

FIG. 6C is an alternative 2-dimensional plan-view illustration of a 3-dimensional plot of an exemplary LDC shown in combination with an exemplary ADC according to aspects of the various embodiments disclosed herein.

FIG. 7 illustrates an exemplary LDC and a representative user interface by which specific variables can be selected for modification in a utility consuming system to achieve a preferred load duration curve according to aspects of the various embodiments disclosed herein.

FIG. 8 illustrates an exemplary LDC and an exemplary Associated Duration Chart (ADC), showing system-generated modifications to achieve a target load duration curve and an optimal load duration curve according to aspects of the various embodiments disclosed herein.

While the present disclosure is susceptible to various modifications and alternative forms, specific embodiments have been shown by way of example in the drawings and will be described in detail below. It should be understood, however, that the present disclosure is not intended to be limited to the particular forms disclosed. Rather, the present disclosure is to cover all modifications, equivalents, and alternatives falling within the spirit and scope of the invention as defined by the appended claims.

### DETAILED DESCRIPTION

While aspects of the present disclosure are susceptible of embodiment in many different forms, there is shown in the drawings and will herein be described in detail representative embodiments of the present disclosure with the understanding that the present disclosure is to be considered as an exemplification of the various aspects and principles of the present disclosure, and is not intended to limit the broad aspects of the present disclosure to the embodiments illustrated. To that extent, elements and limitations that are disclosed, for example, in the Abstract, Summary, and Detailed Description sections, but not explicitly set forth in the claims, should not be incorporated into the claims, singly or collectively, by implication, inference or otherwise.

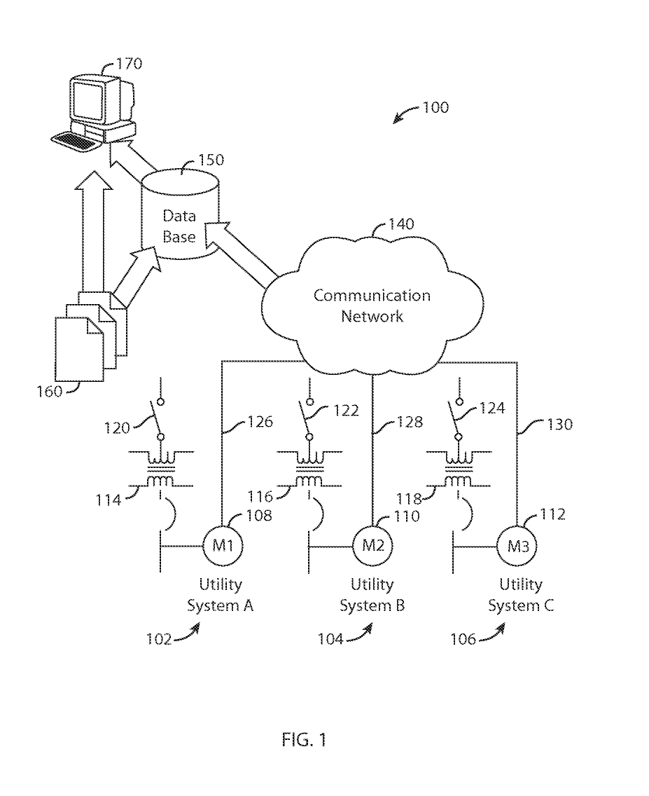

Referring to the drawings, wherein like reference numerals refer to like components throughout the several views, FIG. 1 schematically illustrates an exemplary utility monitoring system, designated generally as 100. The utility monitoring system 100 is shown with a plurality of electrical systems, namely, Utility System A 102, Utility System B 104, and Utility System C 106. The plurality of utility systems 102, 104, 106 (also referred to herein as “utility consuming segments”), individually, collectively, or in different combinations, may represent a utility consuming system, such as a commercial or industrial building, which may include office buildings, hospitals, shopping malls, industrial plants, manufacturing facilities, etc. Alternatively, each utility system 102, 104, 106 can represent a piece of a utility-consuming equipment, such as a boiler or air conditioning unit, within one of the aforementioned buildings.

Depending upon the intended application, such as the particular system being monitored, various combinations of sensors are used. In the illustrated embodiment, each of the utility systems 102, 104, 106 are electrical systems and includes at least one power monitoring device 108, 110, and 112, respectively, in communication with a communication network 140. Each utility system 102, 104, 106 also includes respective transformers 114, 116, 118 coupled to respective switches 120, 122, 124. A power monitoring device is, in some embodiments, an apparatus with the ability to sample, collect, and/or measure one or more electrical characteristics or parameters of the electrical systems 102, 104, 106. By way of non-limiting example, the power monitoring devices 108, 110, 112 may be a PowerLogic® CM4000T Circuit Monitor, a PowerLogic® Series 3000/4000 Circuit Monitor, or a PowerLogic® ION7550/7650 Power and Energy Meter available from Square D Company of Canton, Mass.

Although the utility monitoring system 100 shown in FIG. 1 is a power monitoring system, aspects of the present disclosure are not limited to power monitoring systems. Rather, various aspects of the present disclosure are applicable to any system that monitors any characteristic of utilities, such as those commonly designated by the acronym WAGES, which stands for Water, Air, Gas, Electricity, or Steam. The utility monitoring systems include utility monitoring devices that measure a flow of a utility, and those measured values are referred to herein as a “utility usage rate.” Non-limiting examples of a utility usage rate or “UUR” include: kilowatts (kW), kVAr (kilovolt-ampere reactive or reactance), therms (thm) per unit time (such as per hour or per day), pounds-per-square-inch (PSI) per unit time, hundred cubic feet (CCF) per unit time (e.g., per hour or per day), pounds per unit time (e.g., per hour or per day), and gallons per unit time (e.g., per hour or per day). These UUR values are measured and collected by the utility monitoring devices and can be communicated to a host system. It should be understood that although a specific aspect is described below with reference to a power monitoring system, other aspects of the various embodiments include a utility monitoring system that includes utility monitoring devices that measure characteristics of a WAGES utility.

The communication network 140 illustrated in FIG. 1 is coupled to a database 150, which stores demand interval data (including UUR values) received from the power monitoring devices 108, 110, 112 (or, in other embodiments, utility monitoring devices). The utility companies typically characterize demand as kilowatt of demand or “kWd”, which is a measure of the amount of electrical power that a customer demands from a utility company in a specific interval of time, generally 15 or 30 minutes, though other intervals are possible. In various aspects, the communication network 140 can be wired (e.g., Ethernet, RS485, etc.), wireless (Wi-Fi, Zigbee, cellular, Bluetooth, etc.), or interconnected via other known means of communication.

A user interface, such as host computer 170 or a cloud based computing network, is coupled to the database 150. In another aspect, the host computer 170 is a standalone computer and receives the demand interval data from one or more electronic files 160, which may also be inputted into the database 150, or from the database 150. The power monitoring devices 108, 110, 112 of FIG. 1 monitor demand usage, and transmit their demand interval data to the communication network 140 at periodic (or aperiodic) intervals with appropriate date- and time-stamping information. Alternately, the demand interval data can be extracted manually from the monitoring devices 108, 110, 112 and provided to the host computer 170 via the files 160. In various optional aspects, the data base 150 and/or data files 160 are integrated into the utility systems 102, 104, 106—e.g., into the power monitoring devices 108, 110, 112. For example, when the data is stacked and analyzed, the raw data can be pulled directly from one or more of the utility systems 102, 104, 106 over the communication network 140 directly into the computer 170.

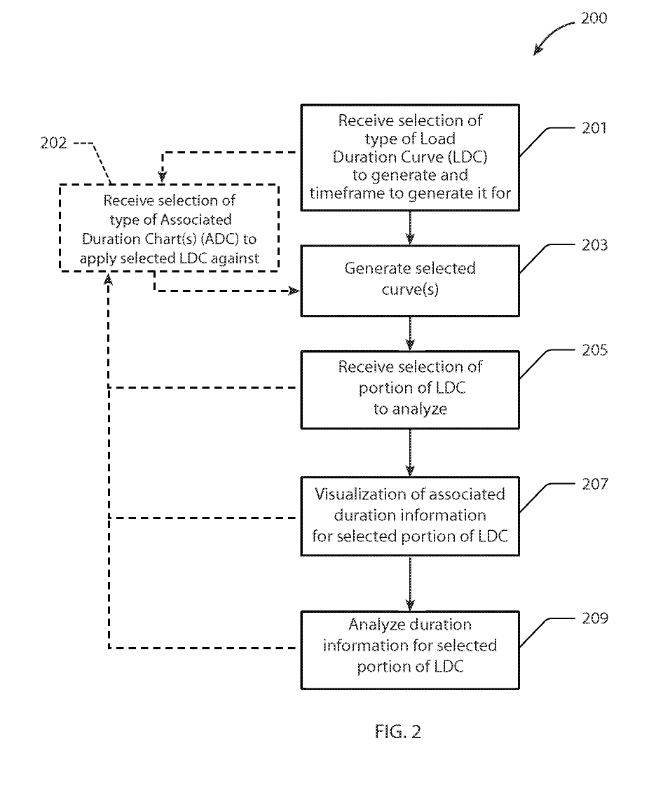

With reference now to the flow chart of FIG. 2, an improved method 200 for regulating usage of at least one utility by a utility consuming system is generally described in accordance with various embodiments. FIG. 2 represents an exemplary algorithm that corresponds to at least some instructions that may be executed by a controller, such as the central processing unit (CPU) of the host computer 170 of FIG. 1, to perform any or all of the following described functions associated with the disclosed concepts. The instructions corresponding to the algorithm 200 can be stored on a non-transitory computer-readable medium, such as on a hard drive or other mass storage device or a memory device.

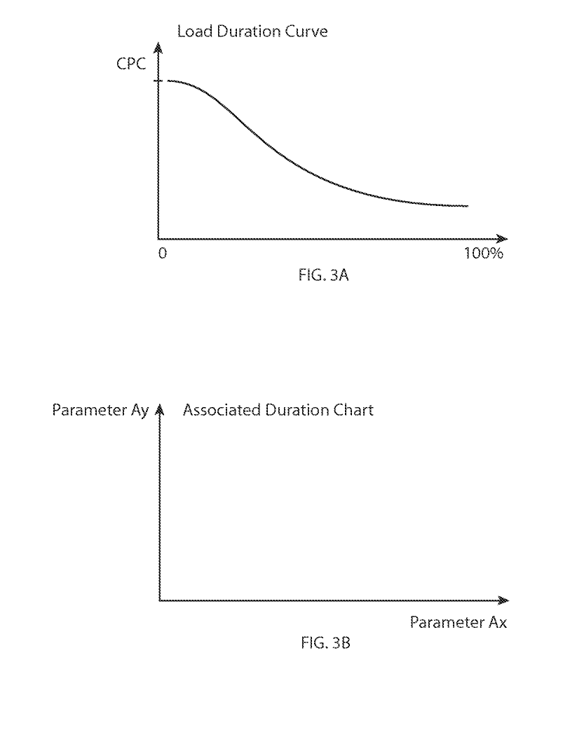

At block 201, the method 200 receives a selection of (or selects) a type of Load Duration Curve (LDC) to generate and the timeframe to generate it for. For instance, a user interface can prompt the user to select the type of LDC they want generated and/or the timeframe within which the LDC should be generated. In general, an LDC is indicative of a percentage of a period time that a value of a utility usage rate is met or exceeded. The term “LDC,” as used herein, has its meaning as commonly understood by those of ordinary skill in the art familiar with utility consumption systems. In the building and industry markets, for example, LDCs can be generated for any one of a number of Capacity Planning Characteristics (CPCs). In the electrical context, examples of a CPC include, but are not limited to, kW demand, peak interval current (amps), and peak interval power factor. For gas, water, steam, and/or air, examples of CPCs include volume per interval, such as cubic feet per second (ft³/sec), and peak flow rate, such as gallons per second (gal/sec). As a point of reference, FIG. 3A illustrates an exemplary LDC, plotting values of a CPC against percentages of measured value from 0-100%. The user may select specific start and end times for the analysis, or may select from one of several predefined time frames (e.g., the prior week, the prior month, the prior year, etc.). Alternatively, selecting the timeframe and/or type of LDC to be generated can be automated. For example, in electrical utility applications, the host computer 170 can automatically select kW demand as a predetermined CPC, and generate the LDC over the prior month as a predefined period of time.

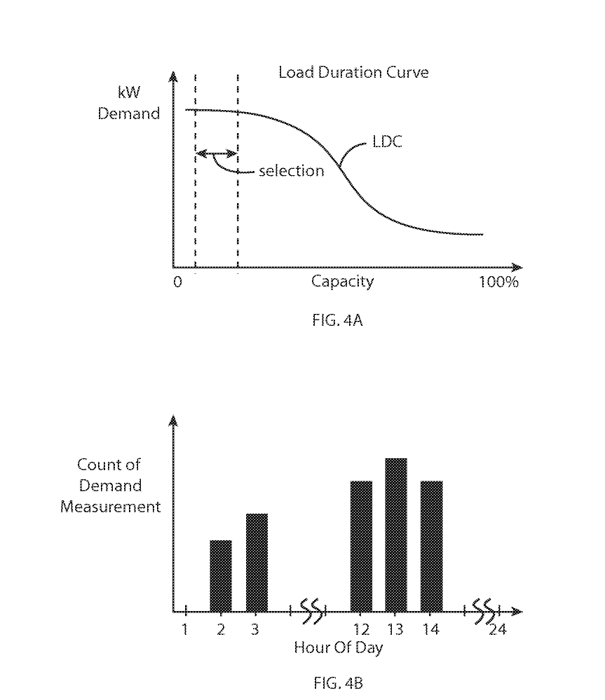

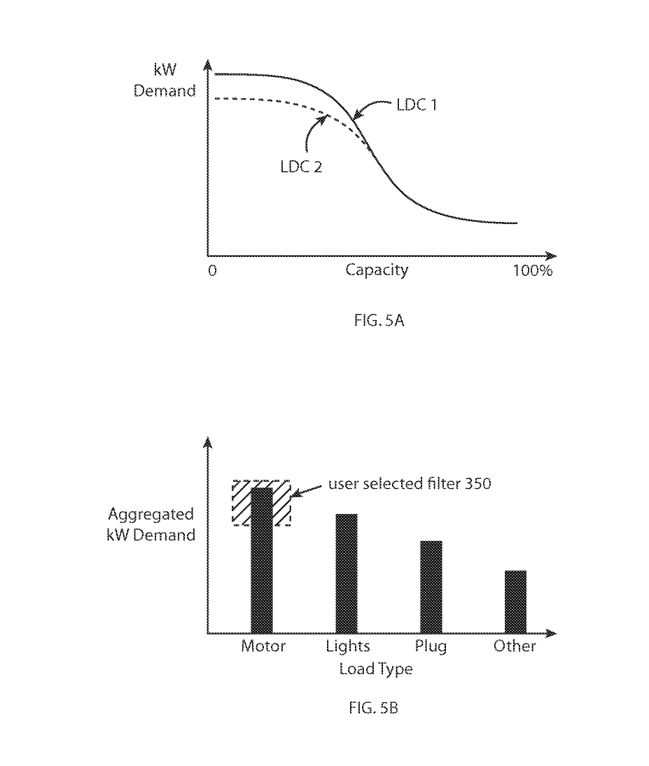

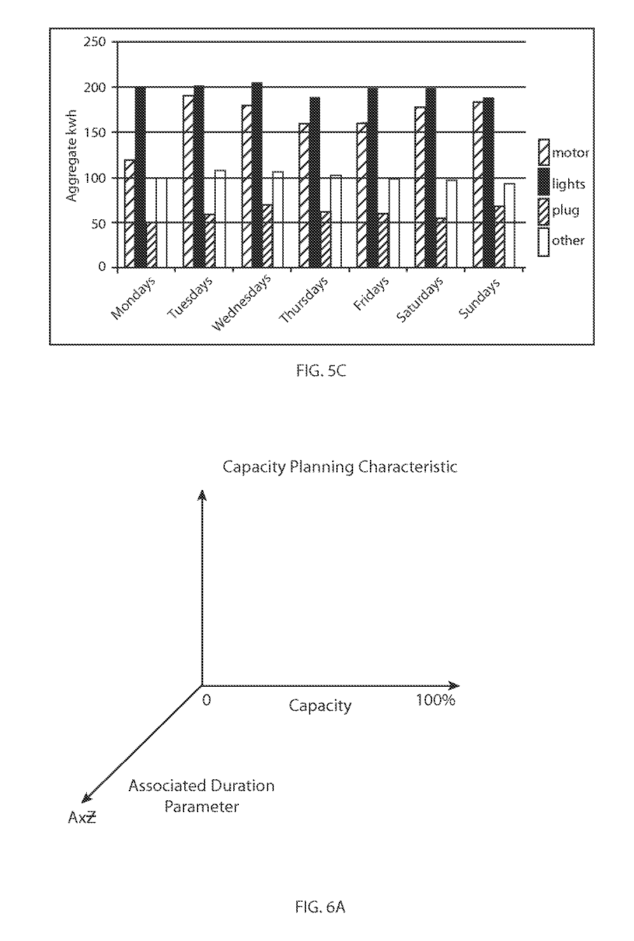

The method 200 may also include receiving a selection of (or selecting) the type of Associated Duration Chart (ADC) to apply the LDC against, as indicated at block 202. For example, a user interface can prompt the user to select which type or types of ADCs they want to evaluate with the LDC. An ADC is a graphical illustration (e.g., a plot) of one or more Associated Duration Parameters relating to the generated LDC. As a point of reference, FIG. 3B illustrates an exemplary, blank ADC. The Parameter Ax and Parameter Ay axes of FIG. 3B are not fixed, as each can have several types of data it can represent. Examples of such parameters include, but are not limited to, time of day, day of week, business hours vs. non-business hours, type of load, department, production line or shift, building name, location, etc. Two specific examples are illustrated in FIGS. 4B and 5B. Capacity planning typically includes the use of categories and metrics to help the user understand the drivers behind periods of high load. Thus, by adding one or more additional “dimensions” to the evaluation of an LDC, where one or more forms of associated duration information are generated and presented along with the LDCs, the user is more fully informed and able to take more meaningful responsive action on the system to reduce peak demand. The system may be optionally configured to offer a default ADC, which the user may then accept or change to another ADC type. In some optional configurations, the user has the capability to return to block 202 from one or more (or all) of the subsequent stages within method 200 and chose a different type of ADC to apply against the LDC.

Referring to FIG. 2, at block 203, the selected LDC and corresponding ADC or ADCs are generated. Optionally, only the selected LDC is generated at block 203, while the corresponding ADC is not generated until after a portion of the LDC is selected, for example, as described below with respect to block 205. To this end, the method 200 may include accumulating demand interval data that is collected by one or more utility monitoring devices, such as the power monitoring devices 108, 110, 112 of FIG. 1. For example, the algorithm 200 receives demand interval data from the power monitoring devices 108, 110, 112 by querying the database 150 for demand data or from the data file(s) 160. The demand interval data may include, for example, a date, the start time of the interval (e.g., 15 minutes or 30 minutes), and the kW value (or, in other embodiments, the UUR value) during the interval. The demand interval data may include demand interval data for a date range, such as one or more weeks, one or more billing months, or one or more years. Once received, the demand interval data is sorted and/or stored. Two exemplary Energy Management software packages that can be used for accumulating and organizing such data is the PowerLogic® ION® Enterprise software package and the ION® EEM software package, both of which are available from Schneider Electric (formerly Power Measurement Ltd.) of Saanichton, B.C. Canada.

The LDC is generated at block 203, at least in part, from the accumulated demand interval data. An exemplary LDC is illustrated in FIG. 4A, which plots actual capacity (“kW Demand”) vs. Capacity Utilization (0% to 100%). Other CPCs that can be used are noted above. An exemplary ADC is illustrated in FIG. 4B, which is a histogram of Count of Demand Measurements vs. Hour of Day.

Referring again to FIG. 2, a selection of a portion of the generated LDC is received (or made) for analysis at block 205. In some embodiments, the user chooses a segment of the LDC that they wish to do a detailed analysis on. The selection can be done manually where the user, for example, sets a baseline or threshold usage rate, the section of the LDC above the baseline/threshold being the selected portion. Alternatively, the user can pick the boundaries of the selection—e.g., select a range of capacity utilization percentages, as seen for example in FIG. 4A. Alternatively, the user can be presented with various default options to select from—e.g., top 10% of LDC, top 15% of LDC, top 20% of LDC, etc. In some embodiments, the selection is predefined and automated. For example, the system can be preset to pick: the top X % of the curve, between X % and Y % of the curve, above a baseline CPC value, above a threshold CPC value, lowest possible, etc. Other predefined selections can be set to the users preferences, such as top % of the curve, or above a certain threshold of kW demand. If the user is comparing the LDC against a baseline (upper or lower threshold), the selection can also be set to be bounded between any significant changes.

In some embodiments, the selected portion of the LDC is evaluated by the system to determine if an alternate portion of the LDC provides a better representation of peak usage. For instance, the user may select a standard characteristic to generate the data for, such as a predetermined period of time. However, in this example, if the selected period of time is too large, one or more outliers in the data may be underrepresented as to their respective significance. This may, in effect, create an inflection point of how many data points to collect and visualize together, with the importance of an outlier being exaggerated before and diminished after this inflection point. In other words, the time frame used for data in the LDC may impact the shape of the curve. To offset this effect, an iterative logic-based analysis can be done by the system to determine if selecting a different characteristic (e.g., a different period of time) will produce a better representation of the data. In an exemplary scenario, the system may be configured to seek curves that fit some profile such that the curves highlight peak demand outliers. For example if there is a significantly large peak demand once per month, viewing an LDC over a year may not illustrate the timing of the occurrence of this peak demand. However, if the data is viewed instead on a monthly cycle, this significant peak demand can be easily seen by the user, and thus more likely analyzed. The system may select a time frame such that the curve has a preset slope leading up to the maximum measurement. In one example, the user may want a large slope, indicating the high demand data points (or outliers) are prominent in the analysis. In another example, the user may want a shallow slope indicating the high demand data points are spread over a larger time. Such an automated time frame selection mechanism will tend to highlight loads and processes responsible for the peak demand in the associated charts.

With continuing reference to FIG. 2, visualization of the associated duration information for the selected portion of the LDC occurs at block 207. For example, FIG. 4A illustrates the user and/or the system interacting with the LDC, selecting a portion of the LDC for analysis (indicated as “selection” in FIG. 4A). FIG. 4B illustrates an exemplary ADC, plotting Demand Measurement Count vs. Hour of Day, that is generated in response to the data-scope selection demonstrated in FIG. 4A. The ADC is indicative of one or more associated duration parameters relating to the selected portion of the first LDC. In practice, some embodiments include the user selecting a portion of the LDC they want to analyze (FIG. 4A). Responsive to the data scope selection, the ADC in FIG. 4B is generated for the user to visualize along with the LDC. The LDC and ADC can be linked such that if a user selects a different portion of the LDC for analysis, the linked ADC updates in response to the new data-scope selection. In this example, the combination of these two charts informs the user that, for the selected portion of the LDC where capacity it at its highest, these highest demand measurements occur between 12:00 and 14:00 hours, peaking at 13:00 hours. The details of this information now allow the user to take more informed action with the goal of reducing peak kW demand.

In another example, the entire data field of information in the ADC of FIG. 4B is always shown—i.e., the histogram information of the associated duration parameters for the whole LDC of FIG. 4A is visualized for the user. When a portion of the LDC is selected, as shown in FIG. 4A, the corresponding portion of data in the ADC is visually highlighted (e.g., enlarged) in FIG. 4B. This optional feature allows the user to interact with the LDC and ADC to provide meaningful information in real-time.

It should be appreciated that multiple, linked ADCs can be viewed at the same time—in one or many graphs. In a non-limiting example, a plurality of different ADCs can be generated that are indicative of various duration parameters relating to a single, selected portion of the LDC. For instance, the method 200 of FIG. 2 can include generating a second ADC (see, e.g., FIG. 5B) that is indicative of one or more additional associated duration parameters relating to the selected portion of the LDC. In another non-limiting example, a plurality of different ADCs can be generated, each of which is indicative of one or more associated duration parameters relating to a different selected portion of the LDC. For instance, the method 200 of FIG. 2 can include receiving a selection of (or selecting) a second portion of the LDC to be analyzed. Responsively, a second ADC is generated that is indicative of one or more associated duration parameters relating to the selected second portion of the LDC. In this example, an indication of a proposed modification of the utility usage of one or more utility consuming segments can be based, at least in part, upon the associated duration parameters indicated in the first ADC, the associated duration parameters indicated in the second ADC, or both. Various permutations of the above examples are also contemplated.

At block 209, the LDC and any corresponding ADCs that have been generated are analyzed. This block can also include recommending the modification of the utility usage of one or more utility consuming segments based, at least in part, upon the associated duration parameters indicated in the ADCs. In some embodiments, the user takes action on the system or a portion/segment of the system. There are several types of actions that can be taken based on the information provided, some short term (e.g., implement a fast change to turn off lights, decrease motor operation, etc.) and others longer term (e.g., initiate capital projects to replace HVAC system with more efficient system, change manufacturing shifts and equipment, etc.). Behavioral changes can include, for example, manual modifications to segments of the system, as well as planning a usage strategy for reduction with both short term and long term projects.

Prior to taking any specific action, the user or system can conduct a “what if” analysis to test out potential changes and their respective impacts, allowing the user/system to identify optimal changes in the system to achieve the desired results. An example of such a “what if” analysis is discussed below and illustrated in FIGS. 5A and 5B. The user/system can also create and set a baseline for subsequent analysis, as well as track the progress of any goals. By way of example, the “what if” analysis can show what reduction can be expected and, after implementation of any changes, the baseline can be used to track the actual results and compare them against the estimated results to ensure the implemented strategy is progressing as expected.

In some embodiments, the method 200 of FIG. 2 includes at least those blocks enumerated above. It is also within the scope and spirit of the present disclosure to omit blocks, include additional blocks, and/or modify the order of the blocks presented. It should be further noted that the method 200 represents a single analysis of a utility consuming system for reducing peak demand. However, it is expected that the method 200 be applied in a repetitive and/or systematic manner.

FIGS. 5A and 5B collectively illustrate an example where the user can take action on the utility-consuming system or a portion thereof in the form of a “what if” analysis, which allows the user to test out potential changes and their respective impacts to identify optimal changes in the system to achieve a desired result. For instance, the user or system can determine one or more modifications to a utility consuming system that will potentially decrease overall peak demand. FIG. 5A illustrates an exemplary LDC, with kW Demand plotted against percent Capacity, juxtaposing a representative “actual” load duration curve LDC1 with a representative “optimized” or “what if” load duration curve LDC2. FIG. 5B illustrates an exemplary ADC that was generated for the load duration curves of FIG. 5A, showing aggregated kilowatt of demand broken down by load type—i.e., Motor, Lights, Plug, and Other (e.g., HVAC, security system, etc.) in the illustrated example. In operation, LDC1 shows the actual LDC for the system in question (e.g., initialized previously at block 203 of FIG. 1). The user or system then inputs a suggested modification to the utility consuming system for analysis. In FIG. 5B, for example, the user selects filter range 350 as a portion of the aggregated Motor load kW Demand for removal. As a result, an optimized load duration curve LDC2 curve is generated in FIG. 5A, showing the user the effect this change would have on the system. The foregoing “what if” analysis provides the user real-time feedback as to what any suggested changes to the system will accomplish for their kW Demand limits. Optionally, the user can also use this feature to analyze the results of increasing a load type. This can be useful, for example, for forecasting or other type of future increase in capacity planning, and the impact on the system.

FIG. 4A can be extended to provide another example of a “what-if” analysis. In FIG. 4A, when the user selects the portion of the LDC that contains high kW demand measurements, the associated histogram of FIG. 4B provides additional details regarding when those high demand measurements occurred. Assuming the analysis system generating the charts of FIGS. 4A and 4B supports “what if” actions, the user or system can select or modify one or more of the histogram bars in FIG. 4B and execute a “what if” analysis. In one example, selecting a histogram bar can provide a breakdown of the load types responsible for the measurements included in that bar. In another example, one or more of the histogram bars of FIG. 4B can be selected for removal or reduction, whereby the system generates an “optimized” or “what if” load duration curve to show the overall impact of removing/reducing those high demand measurements. These actions allow the user to better understand the equipment operation and processes responsible for high peak demands and to formulate strategies for reducing demand to acceptable levels.

In some aspects, the requisite data is aggregated together yet kept stacked such that the data can be “compressed” to one point if needed by the user, or “expanded” if a specific parameter needs to be seen or understood in more detail by the user. This function is possible because data may be aggregated from multiple devices such that when the data is compiled (e.g., from the files 160 or the devices 108 to the host computer 170) the LDC's are layered on top of each other to provide the view in question. Some embodiments require the database keep details on all the energy usage data. In a typical “simple system,” these details may just be demand measurements (kWh) taken in 15 minute intervals. In more complex systems, these details may include additional information like load type, shift, etc, and other information that is relevant to where/how/when/who that demand point comes from.

It should be appreciated that the dimensional views and variations that are available in the basic analysis case, as described above, can also apply in the “what if” scenario case. In other words, the “what if” analysis is not limited to the ADC of FIG. 5B, but can be performed for any of the aforementioned associated duration parameters, such as time of day, day of week, week of month, business hours vs. non-business hours, department, production line or shift, building, location, etc. For instance, FIG. 5C illustrates an exemplary ADC that was generated for the LDC of FIG. 5A, showing aggregated kilowatt of demand broken down by load type and day. The ADC of FIG. 5C, in conjunction with the LDC of FIG. 5A, allows the user to simulate reducing load type (e.g., lighting) on a particular day or days (e.g., weekends).

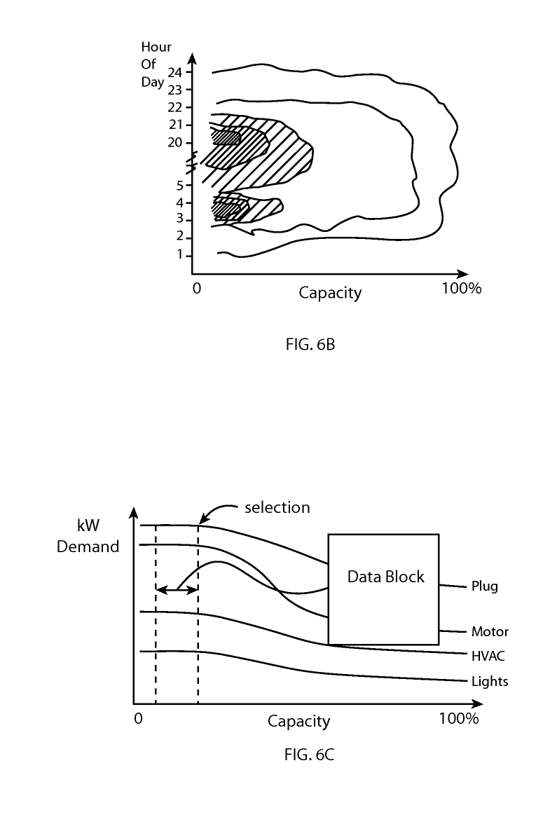

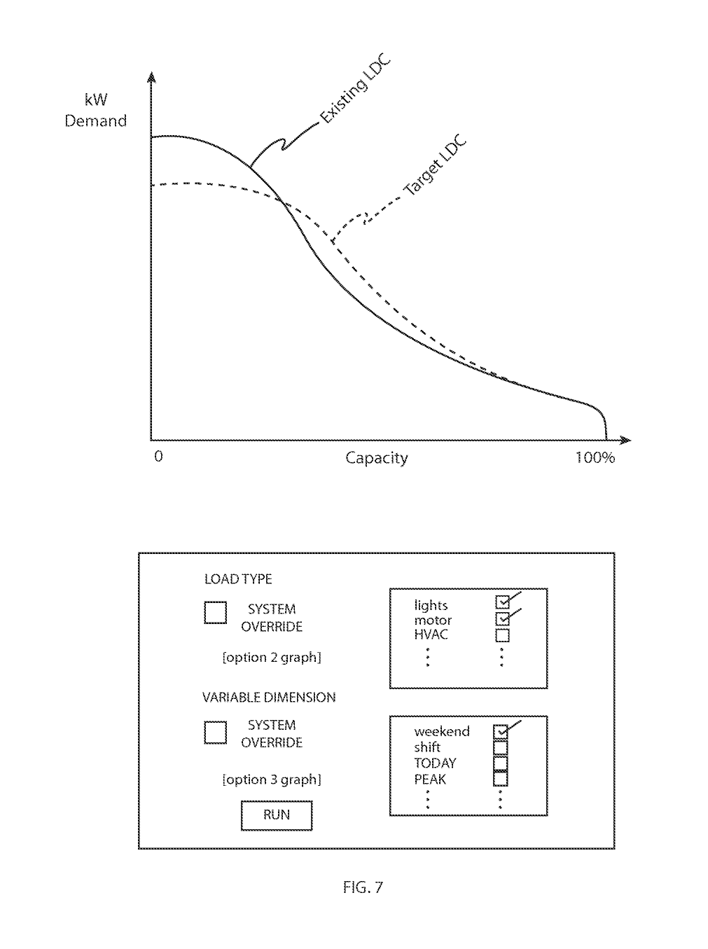

FIG. 6A shows that the LDC and the ADC can be displayed together in a multi-dimensional format. In this example, the percent Capacity and CPC values are plotted on the X- and Y-axes, respectively, both of which make up a typical LDC plot, while the Associated Duration Parameter is plotted along the Z-axis. This allows the user to see a 3-dimensional “peak” of where and/or when a high-load portion of the X-Y occurs. Identification of this impact can now be investigated and acted on (e.g., in blocks 207 and 209 of FIG. 2).

FIG. 6B is a 2-dimensional plan-view illustration of a 3-dimensional plot of an exemplary LDC juxtaposed against an exemplary ADC according to aspects of the various embodiments disclosed herein. In this example, the % Capacity and kW Demand are plotted on the X- and Y-axes, respectively, with the Associated Duration Parameter plotted along the Z-axis as time shown in hours on a 24-hour clock. For ease of visualization, the 3-dimensional mapping of these parameters is shown from a top view in FIG. 6B, with the Z-values (Hours of Day) and X-values (% Capacity) shown and the Y-values (kW Demand) seen in topographical contour-based format. This allows users to visualize at a glance the peaks and lengths of kW Demand, along with the relevant duration parameter, in this example, hours in the day. Peaks of kW Demand are readily seen in FIG. 6B around Hours 20-21 and 3-4. Optionally, the user can then select a desired segment or area and, as a result, details of the LDC for that specific duration parameter are visualized (e.g., kW Demand for the selected contour, hours of day associated with them, and duration of % Capacity). Further details can also be investigated; for example, other associated duration parameters for a selected contour can be visualized (e.g., in a pop-up box or separate window)—i.e. type of load. This information gives the user detailed information to take action on the system, as described above with respect to block 209.

As discussed above with respect to block 205 of FIG. 2, an optional feature is for the system to auto-set and configure itself—e.g., the selected portion of the LDC is evaluated by the system to determine if an alternate segment of the LDC provides a better representation of peak usage. The example provided in FIG. 6B demonstrates that showing the specific duration parameter in more granular detail, i.e., in 10-minute increments instead of 1-hour increments, allows the user or system to more readily identify if the kW Demand peak is a short-term peak or is of sustained duration. The auto-set and configure feature is beneficial in this example because the requisite action that should be taken if the peak is short-term may be different than if the peak is sustained. For example, if the peak is short-term, the information provided to the user may suggest that, to reduce peak-demand, the startup of loads at the 3-Hour and 20-Hour timeframe need to be spread out, or a separate generator with switchover needs to startup these loads which are giving peak demand. If a user is faced with peak-demand charges, this information helps pinpoint where investigation and action can be taken to reduce and/or eliminate charges.

FIG. 6C presents an alternative way of viewing multi-dimensional data with a 2-dimensional graph and accompanying data block. In this example, when queried, a graph is generated with % Capacity vs. kW Demand as the LDC, and the associated duration parameter as the Type of Load representing the ADC. On the stacked area of FIG. 6C, the load types are indicated as, for example, Lights, HVAC, Motor and Plug. As before, the user can select an area of data they wish to investigate (see FIG. 4A and related discussion) and a particular duration parameter (e.g., Motor load only). Further details of these selections can then be shown, for example, in an informational pop-up box (labeled “Data Block” in FIG. 6C) or similar type of display. This manner of visualizing information is beneficial, for example, because it allows the user to see the specifics behind the load duration curve split up by the associated parameters. From this, the user is able to see that the Motor kW Demand is much greater than the HVAC kW Demand, and also has a longer % duration of Capacity. In practice, this feature provides several options when action is taken on the system, from focusing on one type of load to decrease, what time of the day/shift/department/building, to focus their kW Demand reduction efforts on, etc.

FIG. 7 provides an example of a “goal-seeking” feature according to embodiments of the present disclosure. In some configurations, the monitoring system can generate and/or automatically execute a proposed usage strategy to meet short term and/or long term goals (e.g., realize a specific LDC profile). In practice, the user selects or creates a preferred LDC, represented in FIG. 7 as Target LDC. For example, an existing LDC, which represents the systems “actual” load duration curve, may be visualized for the user, for example, as described above with respect to blocks 201 and 203 of FIG. 2. The user may then be provided with various optional target LDCs to choose from. Alternatively, the user can manually modify the Existing LDC to create the Target LDC (e.g., via a user interface). As yet another optional alternative, the user can input specific instructions (e.g., flatter, shorter, specific slope, maximum value, etc.) to create the Target LDC. Any logical combination or variation of the foregoing options is also envisioned. The Target LDC can then be visualized for the user, as seen in FIG. 7.

Prior to, during, or after the Target LDC is established, a user interface, which is schematically illustrated in an exemplary configuration in FIG. 7, allows the end user to identify what specific parameter(s) and variable(s) the system can or will preferably vary to achieve the Target LDC. For instance, the user can identify what load type or types (e.g., lighting, motor, HVAC, etc.) can/should be varied, as well as the variable dimension (e.g., during the weekend, during a particular day, during a particular shift, etc.) over which the load(s) can/should be varied to achieve the Target LDC. Also illustrated is the ability for the system to override the user variables (i.e., Load Types and Variable Dimensions) that are used to reach the Target LDC. This override option exists to allow the system to override the variables selected by the user if it cannot achieve the target based on a limited number or type of variables to manipulate during the “goal-seeking” routine.

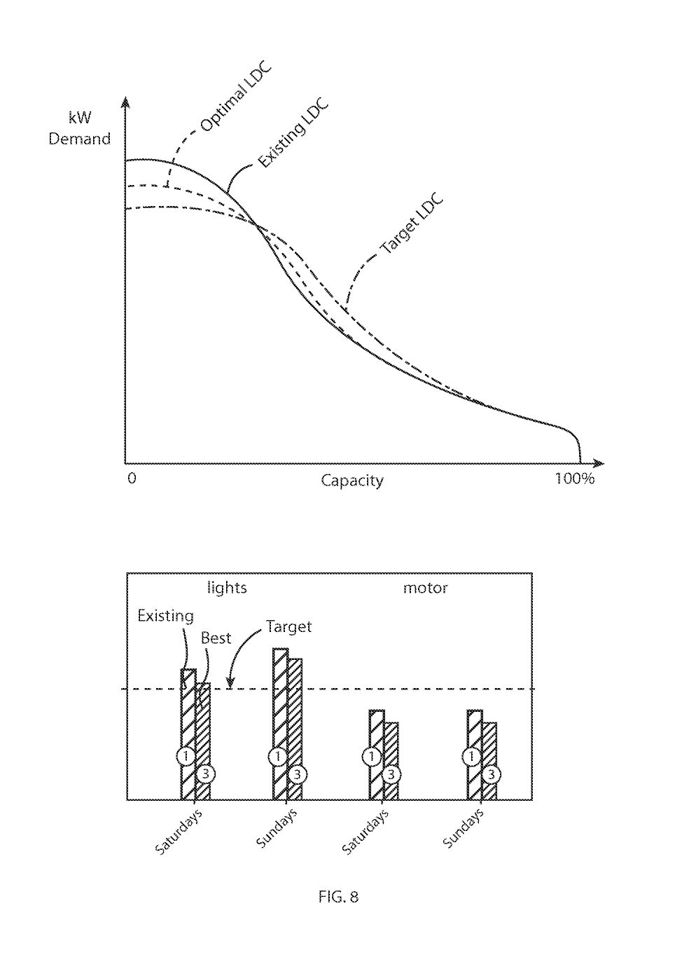

Once all of the requisite input variables are provided, the goal-seek routine is executed. The goal-seeking routine then returns target/recommended values for the loads and variable dimensions to achieve the Target LDC. From this, the user and/or monitoring system can take action to modify the utility-consuming system (or segments thereof) as necessary. By way of non-limiting example, FIG. 8 results from initiation of the RUN button seen at the bottom of FIG. 7 with options shown so the user can have a detailed understanding of several what-if scenarios. The Existing LDC and Target LDC from FIG. 7 are visualized again in FIG. 8 Likewise, an Optimal LDC is generated and visualized in FIG. 8. A corresponding ADC, such as the ADC shown in FIG. 8 that graphs aggregated kilowatt of demand broken down by load type (e.g., lights and motors) and day (e.g., Saturdays and Sundays), is also visualized for the Existing LDC and Target LDC.

While particular embodiments and applications of the present disclosure have been illustrated and described, it is to be understood that this disclosure is not limited to the precise construction and compositions disclosed herein and that various modifications, changes, and variations can be apparent from the foregoing descriptions without departing from the spirit and scope of the invention as defined in the appended claims.

What is claimed is:

1. A method of analyzing usage of at least one utility by a utility consuming system having a plurality of utility consuming segments, the method comprising:
generating a first load duration curve (LDC);
receiving a selection of a portion of the first LDC to be analyzed;
generating a first associated duration chart (ADC) indicative of one or more associated duration parameters relating to the selected portion of the first LDC; and
storing the generated first ADC in association with the generated first LDC.

2. The method of claim 1, further comprising generating an indication of a proposed modified usage of the at least one utility by at least one of the plurality of utility consuming segments based, at least in part, upon the one or more associated duration parameters indicated in the first ADC

3. The method of claim 1, further comprising receiving a selection of a type of LDC prior to the generating of the first LDC, wherein the first LDC is generated as the selected type of LDC.

4. The method of claim 3, wherein the selection of the type of LDC includes a kW demand LDC, a peak interval current LDC, or a peak interval power factor LDC.

5. The method of claim 1, further comprising receiving a selection of a timeframe prior to the generating of the first LDC, wherein the first LDC is generated for the selected timeframe.

6. The method of claim 1, further comprising receiving a selection of a type of ADC prior to the generating of the first ADC, wherein the first ADC is generated as the selected type of ADC.

7. The method of claim 1, further comprising generating a plurality of ADCs indicative of a plurality of associated duration parameters relating to the selected portion of the first LDC.

8. The method of claim 1, wherein the selection of the portion of the first LDC to be analyzed is carried out automatically.

9. The method of claim 1, further comprising analyzing the selected portion of the first LDC to determine if an alternate portion of the first LDC provides a better representation of a peak usage of the at least one utility.

10. The method of claim 1, further comprising:
receiving a selection of a second portion of the first LDC to be analyzed;
generating a second associated duration chart (ADC) indicative of one or more associated duration parameters relating to the selected second portion of the first LDC;
modifying usage of the at least one utility by at least one of the plurality of utility consuming segments based, at least in part, upon the one or more associated duration parameters indicated in the first ADC, the one or more associated duration parameters indicated in the second ADC, or both.

11. The method of claim 1, further comprising generating a second LDC, wherein the first LDC represents an actual LDC and the second LDC represents an optimized LDC.

12. The method of claim 1, further comprising generating a second LDC and a third LDC, wherein the first LDC represents an actual LDC, the second LDC represents a target LDC, and the third LDC represents an optimal LDC.

13. The method of claim 1, wherein the first LDC and the first ADC are displayed together in a 3-dimensional format.

14. The method of claim 1, wherein the first LDC is indicative of a percentage of a period time that a value of a utility usage rate is met or exceeded.

15. The method of claim 1, further comprising determining at least one change to the utility consuming system that will decrease overall peak demand during a measured period.

16. The method of claim 1, further comprising accumulating demand interval data collected by at least one utility monitoring device, the demand interval data including a number of utility usage rate values and associated temporal data, wherein the first LDC is generated, at least in part, from at least some of the accumulated demand interval data.

17. The method of claim 15, wherein the utility usage rate is kilowatts, gallons per unit time, or cubic feet per unit time.

18. One or more non-transitory, machine-readable storage media including instructions which, when executed by one or more processors, cause the one or more processors to perform operations associated with a utility monitoring system, the operations comprising:
accumulating demand interval data collected by at least one utility monitoring device in the utility monitoring system, the demand interval data including a number of utility usage rate values and associated temporal data;
generating a load duration curve (LDC) from at least some of the accumulated demand interval data;
generating an associated duration chart (ADC) indicative of one or more associated duration parameters relating to a selected portion of the LDC; and
storing the generated first ADC in association with the generated first LDC.

19. A monitoring system for monitoring usage of at least one utility by a utility consuming system having a plurality of utility consuming segments, the monitoring system comprising:
at least one utility monitoring device configured to accumulate demand interval data from the utility consuming system, the demand interval data including a number of utility usage rate values and associated temporal data;
a display device;
a user interface; and
at least one controller configured to:
receive, via the user interface, a selection of a type of load duration curve (LDC) to be generated;
receive, via the user interface, a selection of a type of associated duration chart (ADC) to be generated;
generate an LDC based on at least some of the accumulated demand interval data and the selected type of LDC;
generate an ADC indicative of one or more associated duration parameters relating to the generated LDC, the ADC being generated based on the selected type of ADC; and
command the display device to display the generated LDC and the generated ADC.
